(19) United States
(12) Patent Application Publication
(10) Pub. No.: US 2011/0063012 A1
(43) Pub. Date: Mar. 17, 2011

(54) CIRCUIT ARRANGEMENT

(76) Inventors: Kok Lim CHAN, Singapore (SG); Andreas Astuti LEE, Singapore (SG); Minkyu JE, Singapore (SG)

(21) Appl. No.: 12/875,568

(22) Filed: Sep. 3, 2010

Related U.S. Application Data
(60) Provisional application No. 61/241,535, filed on Sep. 11, 2009.

(51) Int. Cl. H03L 5/00; H01L 25/00

(52) U.S. Cl. 327/333; 327/565

(57) ABSTRACT

A circuit arrangement is provided. The circuit arrangement includes a first transistor, a second transistor, a third transistor, and a fourth transistor respectively comprising a first terminal, a second terminal, and a control terminal, a first capacitor and a second capacitor respectively comprising a first terminal and a second terminal, an inverter comprising an input terminal and an output terminal, and a circuit arrangement input terminal and a first circuit arrangement output terminal, wherein the first terminals of the first transistor, the second transistor and the third transistor are connected with each other, wherein the second terminal of the first transistor is connected to the control terminal of the second transistor and to the first terminal of the first capacitor, and wherein the second terminal of the second transistor is connected to the control terminal of the first transistor, to the control terminal of the third transistor, and to the first terminal of the second capacitor, wherein the second terminal of the first capacitor is connected to the input terminal of the inverter, and wherein the second terminal of the second capacitor is connected to the output terminal of the inverter, wherein the output terminal of the inverter is connected to the control terminal of the fourth transistor, wherein the second terminal of the third transistor is coupled to the first terminal of the fourth transistor, wherein the circuit arrangement input terminal is connected to the input terminal of the inverter, wherein the first circuit arrangement output terminal is connected between the second terminal of the third transistor and the first terminal of the fourth transistor.

### CROSS-REFERENCE TO RELATED APPLICATION

This application claims priority to U.S. provisional application No. 61/241,535 filed on 11 Sep. 2009, the content of which is incorporated herein by reference in its entirety for all purposes.

### TECHNICAL FIELD

Various embodiments relate generally to a circuit arrangement.

### BACKGROUND

For ultra low power applications such as bio-implanted device and sensor nodes system, the power available for these applications from battery, energy harvester or inductive power link is very limited. The total power consumption of these applications is typically constrained to the μW region. A successive approximation (SAR) analog-to-digital converter (ADC) is usually used for these applications because of the low power consumption of the SAR ADC [1].

A conventional SAR ADC 100 as shown in FIG. 1 usually includes a SAR Control Logic 102, a capacitor array 104, a plurality of switches 106 connected to the capacitor array 104, and a comparator 108. To reduce the power consumption of the SAR ADC 100, it is preferable to operate the SAR Control Logic 102 at sub-threshold level while the switches 106 and the comparator 108 are operated by a much larger supply voltage. For example, for a 0.18 μm CMOS process, a lower supply voltage may be about 0.3V and a higher supply voltage may be about 1.8V. Level shifters are usually used to interface between a lower supply voltage VDDL and a higher supply voltage VDDH.

FIG. 2 shows a conventional level shifter 200 [2]. The level shifter 200 has a first transistor 202, a second transistor 204, a third transistor 206, a fourth transistor 208 and an inverter 210. The third transistor 206 is driven by an input voltage Vin and the fourth transistor 208 is driven by a complementary of the input voltage provided by the inverter 210. The first transistor 202 and the second transistor 204 are cross-coupled to provide positive feedback. The third transistor 206 and the fourth transistor 208 are designed to be much stronger than the first transistor 202 and the second transistor 204 so that the output voltage can be toggled between VDDH and 0V. However, when the input is at sub-threshold level, the third transistor 206 and the fourth transistor 208 could not overcome the positive feedback of the first transistor 202 and the second transistor 204. Thus, the level shifter 200 could not work with sub-threshold input [3]. Further, the level shifter 200 is not energy efficient as its internal nodes are switched between VDDH and 0V on every cycle. This leads to increased power dissipation in the parasitic capacitances.

Another way to achieve the level shifting is by means of a clock boosting circuit 300 shown in FIG. 3. The clock boosting circuit 300 can be applied in a pipelined ADC [4]. The circuit 300 has a first transistor 302, a second transistor 304, a third transistor 306, a fourth transistor 308, an inverter 310, a first capacitor 312 and a second capacitor 314. When an input voltage Vin is supplied to the circuit 300, the first capacitor 312 and the second capacitor 314 are both charged to VDDL. Subsequently, when the input voltage Vin becomes 0V, the output of the inverter 310 becomes VDDL. This causes an output voltage Vout of the circuit 300 to rise to 2VDDL. When the input voltage Vin becomes high, the fourth transistor 308 is turned on to short the output voltage Vout to ground. This approach cannot work with sub-threshold input. With sub-threshold input, the fourth transistor 308 will not be strong enough to ground the output voltage Vout. Another limitation of the circuit 300 is that VDDH is constrained to 2VDDL.

FIG. 4 shows a conventional level shifter 400 for a SAR ADC with split power supplies [5]. The level shifter 400 has a first transistor 402, a second transistor 404, a third transistor 406, a fourth transistor 408, a fifth transistor 410, an inverter 412 and a capacitor 414. When an input voltage Vin of the level shifter 400 is at VDDL, the output of the inverter 412 is 0V. This causes the second transistor 404 to turn on which causes an output voltage Vout of the level shifter 400 of VDDH. At the same time, the first transistor 402 turns on to charge the capacitor 414 to VDDL. When input voltage Vin is at 0V, the third transistor 408 turns on and a voltage of 2VDDL is supplied to an inverter formed by the fourth and fifth transistors (408, 410). The disadvantage of this level shifter 400 is VDDH needs to be constrained to 2VDDL. Otherwise, when the input voltage Vin is 0V, the fourth transistor 408 may not turn off

Further, a coupled level shifter [6] and a level shifter with switchover to low power mode [7] are also not compatible to sub-threshold input. A conventional sub-threshold compatible level-shifter [3] requires Zero V_{T} NMOS transistors. Therefore, the conventional level shifters either cannot work at sub-threshold level or are not energy efficient.

### SUMMARY

According to one embodiment of the present invention, a circuit arrangement is provided. The circuit arrangement includes a first transistor, a second transistor, a third transistor, and a fourth transistor respectively comprising a first terminal, a second terminal, and a control terminal, a first capacitor and a second capacitor respectively comprising a first terminal and a second terminal, an inverter comprising an input terminal and an output terminal, and a circuit arrangement input terminal and a first circuit arrangement output terminal, wherein the first terminals of the first transistor, the second transistor and the third transistor are connected with each other, wherein the second terminal of the first transistor is connected to the control terminal of the second transistor and to the first terminal of the first capacitor, and wherein the second terminal of the second transistor is connected to the control terminal of the first transistor, to the control terminal of the third transistor, and to the first terminal of the second capacitor, wherein the second terminal of the first capacitor is connected to the input terminal of the inverter, and wherein the second terminal of the second capacitor is connected to the output terminal of the inverter, wherein the output terminal of the inverter is connected to the control terminal of the fourth transistor, wherein the second terminal of the third transistor is coupled to the first terminal of the fourth transistor, wherein the circuit arrangement input terminal is connected to the input terminal of the inverter, wherein the first circuit arrangement output terminal is connected between the second terminal of the third transistor and the first terminal of the fourth transistor.

In one embodiment, the circuit arrangement includes a fifth transistor and a sixth transistor respectively including a first terminal, a second terminal and a control terminal, a second circuit arrangement output terminal, wherein the first terminal of the fifth transistor is coupled to the first terminals of the first, second and third transistor, wherein the control terminal of the fifth transistor is coupled to the second terminal of the first transistor, wherein the first terminal of the sixth transistor is coupled to the second terminal of the fifth transistor, wherein the control terminal of the sixth transistor is coupled to the circuit arrangement input terminal, and wherein the second circuit arrangement output terminal is connected between the second terminal of the fifth transistor and the first terminal of the sixth terminal.

In one embodiment, the inverter includes a first voltage input terminal and a second voltage input terminal, and wherein the inverter is adapted to set the output terminal of the inverter to one of the voltages supplied to the first voltage input terminal and the second voltage input terminal, respectively, in dependence on the voltage supplied to the input terminal of the inverter.

In one embodiment, the first terminals of the first transistor, the second transistor, the third transistor, and the fifth transistor are set to a high power supply voltage VDDH, the first voltage supply terminal set to a low power supply voltage VDDL, whereas the second voltage supply terminal as well as the second terminals of the fourth and sixth transistor are respectively set to a fixed voltage which is lower than the low power supply voltage VDDL.

In one embodiment, the circuit arrangement is adapted such that it operates at a plurality of ratios [VDDH voltage/VDDL voltage].

In one embodiment, the circuit arrangement is adapted such that, during the operation of the circuit arrangement, each of the first capacitor and the second capacitor is charged to VDDH-VDDL.

In one embodiment, the circuit arrangement is adapted such that, during the operation of the circuit arrangement, the voltages of all internal nodes only change by

VDDL, respectively.

In one embodiment, the VDDL voltage is a sub-threshold voltage with regard to the threshold voltage of the third, fourth, fifth and sixth transistor.

In one embodiment, the VDDL voltage is up to 30% higher or up to 30% lower than the threshold voltage of the third, fourth, fifth and sixth transistor.

In one embodiment, the third, fourth, fifth and sixth transistor are respectively 1.8V transistors having a threshold voltage of 0.4V, wherein the VDDL voltage is set to 0.3V.

In one embodiment, the circuit arrangement is adapted such that, during the operation of the circuit arrangement, the voltage Vout generated at the first circuit arrangement output terminal and the second circuit arrangement output terminal respectively ranges between the fixed voltage and VDDH.

In one embodiment, the VDDH voltage is below the maximum drain source voltage Vds.

In one embodiment, the third, fourth, fifth and sixth transistor are respectively 1.8V transistors, and wherein the VDDH voltage is 1.8V.

In one embodiment, the circuit arrangement is a level shifter.

In one embodiment, the level shifter is part of a circuitry in which slower transistor switching speeds of the third, fourth, fifth and sixth transistor due to sub-threshold voltage transistor operations can be tolerated.

In one embodiment, the level shifter is part of a SAR analogue-to-digital converter.

In one embodiment, the first transistor, the second transistor, the third transistor, fourth transistor, fifth transistor, and sixth transistor respectively are field effect transistors, wherein the first terminals and second terminals of the first to sixth transistors respectively are source/drain terminals, and wherein the control terminals of the first to sixth transistors respectively are gate terminals.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic diagram of a conventional successive approximation (SAR) analog-to-digital converter (ADC).

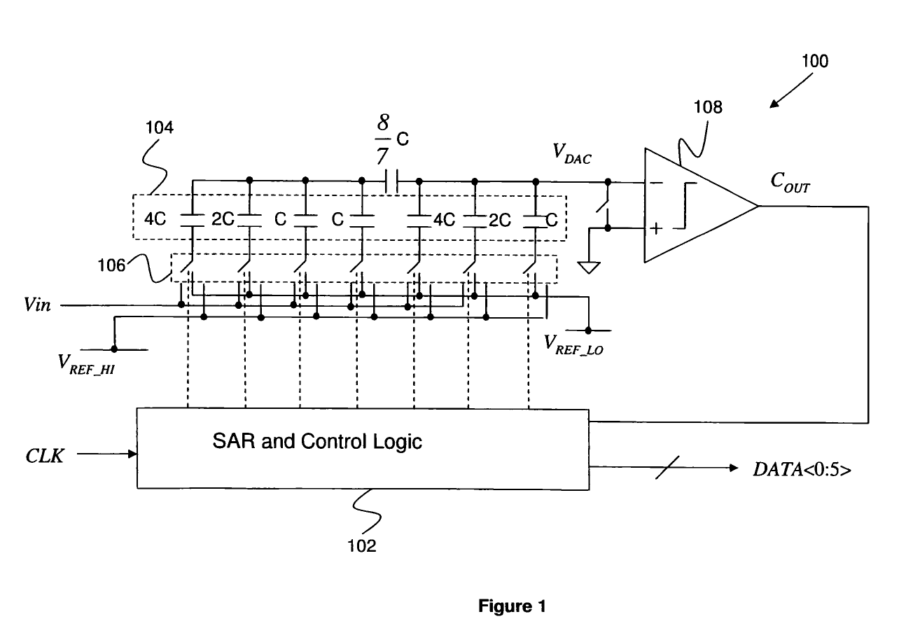

FIG. 2 shows a schematic diagram of a conventional level shifter.

FIG. 3 shows a schematic diagram of a conventional clock boosting circuit.

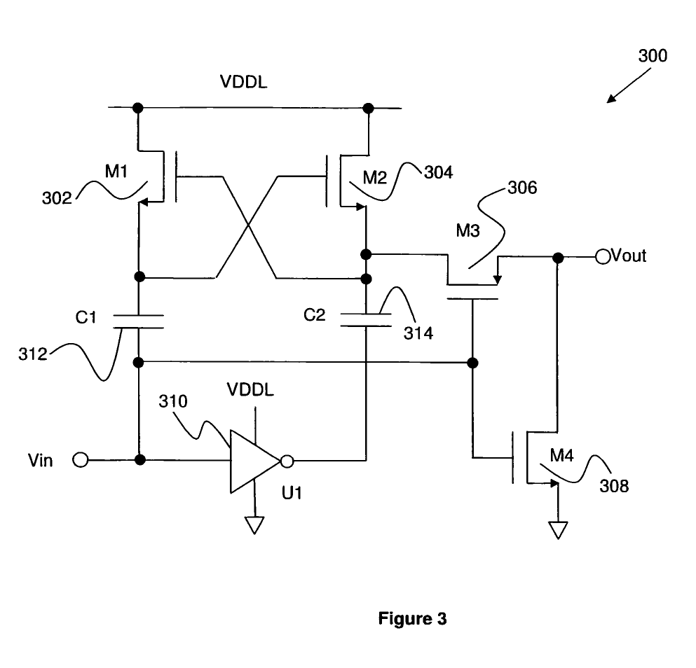

FIG. 4 shows a schematic diagram of a conventional level shifter.

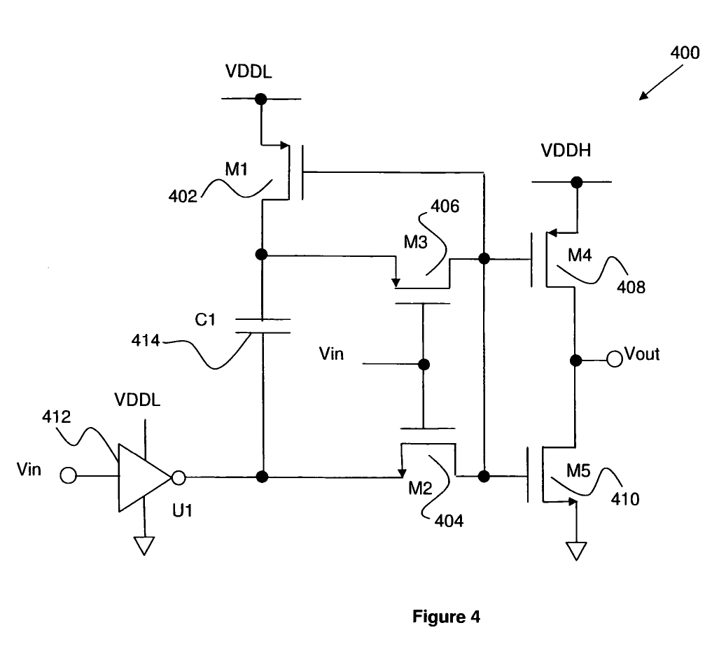

FIG. 5 shows a schematic diagram of a circuit arrangement according to one embodiment of the present invention.

FIGS. 6a-c show graphical plots of input voltage, output voltage and current consumption for a circuit arrangement according to one embodiment of the present invention.

FIGS. 6d-f show graphical plots of input voltage, output voltage and current consumption for the conventional level shifter 200 of FIG. 2

### DETAILED DESCRIPTION

Embodiments of a circuit arrangement will be described in detail below with reference to the accompanying figures. It will be appreciated that the embodiments described below can be modified in various aspects without changing the essence of the invention.

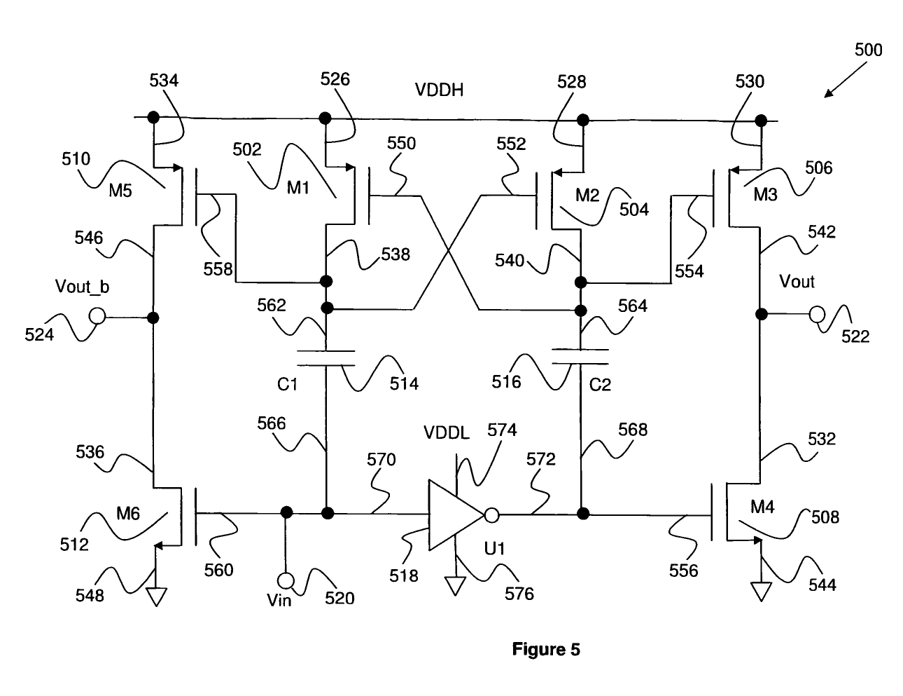

FIG. 5 shows a schematic diagram of a circuit arrangement 500. The circuit arrangement 500 includes a first transistor 502, a second transistor 504, a third transistor 506, and a fourth transistor 508. The circuit arrangement 500 also includes a first capacitor 514, a second capacitor 516 and an inverter 518. The circuit arrangement 500 includes a circuit arrangement input terminal 520 and a first circuit arrangement output terminal 522.

Each of the first to sixth transistors 502-512 has a first terminal (526, 528, 530, 532), a second terminal (538, 540, 542, 544), and a control terminal (550, 552, 554, 556) respectively. Each of the first capacitor 514 and the second capacitor 516 includes a first terminal (562, 564) and a second terminal (566, 568) respectively. The inverter 518 includes an input terminal 570 and an output terminal 572. The inverter 518 also includes a first voltage input terminal 574 and a second voltage input terminal 576. The inverter 518 is adapted to set the output terminal 572 of the inverter 518 to one of the voltages supplied to the first voltage input terminal 574 and the second voltage input terminal 576, respectively, in dependence on the voltage supplied to the input terminal 570 of the inverter 518.

The first terminals (526, 528, 530) of the first transistor 502, the second transistor 504 and the third transistor 506 are connected with each other. The second terminal 538 of the first transistor 502 is connected to the control terminal 552 of the second transistor 504 and to the first terminal 562 of the first capacitor 514. The second terminal 540 of the second transistor 504 is connected to the control terminal 550 of the first transistor 502, to the control terminal 554 of the third transistor 506, and to the first terminal 564 of the second capacitor 516. The second terminal 566 of the first capacitor 514 is connected to the input terminal 570 of the inverter 518. The second terminal 568 of the second capacitor 516 is connected to the output terminal 572 of the inverter 518.

The output terminal 572 of the inverter 518 is connected to the control terminal of 556 of the fourth transistor 508. The second terminal 542 of the third transistor 506 is coupled to the first terminal 532 of the fourth transistor 508. The circuit arrangement input terminal 520 is connected to the input terminal 570 of the inverter 518. The first circuit arrangement output terminal 522 is connected between the second terminal 542 of the third transistor 506 and the first terminal 532 of the fourth transistor 508.

The circuit arrangement 500 further includes a fifth transistor 510, a sixth transistor 512 and a second circuit arrangement output terminal 524. Each of the fifth transistor 510 and the sixth transistor 512 has a first terminal (534, 536), a second terminal (546, 548), and a control terminal (558, 560) respectively. The second circuit arrangement output terminal 524 is a complementary output of the first circuit arrangement output terminal 522.

The first terminal 534 of the fifth transistor 510 is coupled to the first terminals (526, 528, 530) of the first, second and third transistors (502, 504, 506). The control terminal 558 of the fifth transistor 510 is coupled to the second terminal 538 of the first transistor 502. The first terminal 536 of the sixth transistor 512 is coupled to the second terminal 546 of the fifth transistor 510. The control terminal 560 of the sixth transistor 512 is coupled to the circuit arrangement input terminal 520. The second circuit arrangement output terminal 524 is connected between the second terminal 546 of the fifth transistor 510 and the first terminal 536 of the sixth terminal 512.

In one embodiment, the first to sixth transistors (502, 504, 506, 508, 510, 512) may be field effect transistors. The first terminals (526, 528, 530, 532, 534, 536) and second terminals (538, 540, 542, 544, 546, 548) of the first to sixth transistors (502, 504, 506, 508, 510, 512) are source/drain terminals. That is, if the first terminal of one transistor is a source terminal, the second terminal of the same transistor is a drain terminal, and vice versa. The control terminals (550, 552, 554, 556, 558, 560) of the first to sixth transistors (502, 504, 506, 508, 510, 512) are gate terminals.

The first terminals (526, 528, 530, 534) of the first transistor 502, the second transistor 504, the third transistor 506, and the fifth transistor 510 are set to a high power supply voltage VDDH. In one embodiment, the VDDH voltage may be below the maximum drain source voltage Vds. For example, if the third, fourth, fifth and sixth transistors (506, 508, 510, 512) are respectively 1.8V transistors, the VDDH voltage may be about 1.8V.

In one embodiment, the first voltage supply terminal 574 of the inverter 518 is set to a low power supply voltage VDDL. In one embodiment, the VDDL voltage may be a sub-threshold voltage with regard to the threshold voltage of the third, fourth, fifth and sixth transistors (506, 508, 510, 512). The VDDL voltage may be up to 30% higher or up to 30% lower than the threshold voltage of the third, fourth, fifth and sixth transistors (506, 508, 510, 512). For example, if the third, fourth, fifth and sixth transistors (506, 508, 510, 512) are respectively 1.8V transistors having a threshold voltage of about 0.4V, the VDDL voltage may be set to about 0.3V.

The second voltage supply terminal 576 of the inverter 518 and the second terminals (544, 548) of the fourth and sixth transistors (508, 512) are respectively set to a fixed voltage which is lower than the low power supply voltage VDDL. In one embodiment, the fixed voltage may be set to a voltage of 0V (i.e. set to ground).

In one embodiment, the circuit arrangement 500 is a level shifter. The level shifter 500 may be part of a circuitry in which slower transistor switching speeds of the third, fourth, fifth and sixth transistors (506, 508, 510, 512) due to sub-threshold voltage transistor operations can be tolerated. In one embodiment, the level shifter 500 may be part of a SAR analogue-to-digital converter.

Details of the operation of the circuit arrangement 500 are described in the following. For ease of explanation, the second voltage supply terminal 576 of the inverter 518 and the second terminals (544, 548) of the fourth and sixth transistors (508, 512) are assumed to be set at 0V in the following description. Nevertheless, a skilled person would understand that the second voltage supply terminal 576 of the inverter 518 and the second terminals (544, 548) of the fourth and sixth transistors (508, 512) may be set at any value lower than the low power supply voltage VDDL. To ensure proper operation of the circuit arrangement 500, the VDDL voltage may be turned on before the VDDH voltage at start-up.

Initially, when both the first capacitor 514 and the second capacitor 516 are discharged, a 0V may be measured at the input terminal 570 or the output terminal 572 of the inverter 518. As a result, the second transistor 504 or the first transistor 502 may turn on, depending if the 0V is measured at the input terminal 570 or the output terminal 572 of the inverter 518. Eventually, the first capacitor 514 and the second capacitor 516 are charged to a voltage of (VDDH-VDDL). When the voltage at the circuit arrangement input terminal 520 is 0V, the voltage supplied to the input terminal 570 of the inverter 518 is 0V. The inverter 518 thus sets the voltage at the output terminal 572 of the inverter 518 to VDDL. Thus, the voltage supplied to the control terminals (554, 556) of the third and fourth transistors (506, 508) is VDDH and VDDL respectively. As a result, the voltage at the first circuit arrangement output terminal 522 is 0V.

When the voltage at the circuit arrangement input terminal 520 is VDDL, the voltage supplied to the input terminal 570 of the inverter 518 is VDDL. The inverter thus sets the voltage at the output terminal 572 of the inverter 518 to 0V. Thus, the voltage supplied to the control terminals (554, 556) of the third and fourth transistors (506, 508) is (VDDH-VDDL) and 0V respectively. As a result, the voltage at the first circuit arrangement output terminal 522 is VDDH.

Since the second circuit arrangement output terminal 524 is the complementary output of the first circuit arrangement output terminal 522, the operations of the fifth and sixth transistors (510, 512) can be reasoned in a similar manner. When the voltage at the circuit arrangement input terminal 520 is 0V, the voltage supplied to the control terminals (558, 560) of the fifth and sixth transistors (510, 512) is (VDDH-VDDL) and 0V respectively. As a result, the voltage at the second circuit arrangement output terminal 524 is VDDH. When the voltage at the circuit arrangement input terminal 520 is VDDL, the voltage supplied to the control terminals (558, 560) of the fifth and sixth transistors (510, 512) is VDDH and VDDL respectively. As a result, the voltage at the second circuit arrangement output terminal 524 is 0V.

The circuit arrangement 500 operates at a plurality of ratios [VDDH voltage/VDDL voltage]. The circuit arrangement 500 does not require the ratio [VDDH voltage/VDDL voltage] to be constrained to certain values. For example, the circuit arrangement 500 does not require the VDDL voltage to be greater than half of the VDDH voltage. The voltages of all the internal nodes of the circuit arrangement 500 only change by VDDL respectively. The voltage generated at the first circuit arrangement output terminal 522 and the voltage generated at the second circuit arrangement output terminal 524 respectively range between the fixed voltage (e.g. 0V) of the second voltage supply terminal 576 of the inverter 518 and the second terminals (544, 548) of the fourth and sixth transistors (508, 512), and VDDH.

Since the first capacitor 514 and the second capacitor 516 are only charged once, and all the internal nodes only change by VDDL, the power dissipation due to the charging and discharging of the parasitic capacitances is greatly minimized. The circuit arrangement (e.g. level shifter) 500 is energy efficient.

Further, the third and fourth transistors (506, 508) can operate in sub-threshold when VDDL is small. Thus, the circuit arrangement (e.g. level shifter) 500 is sub-threshold input compatible.

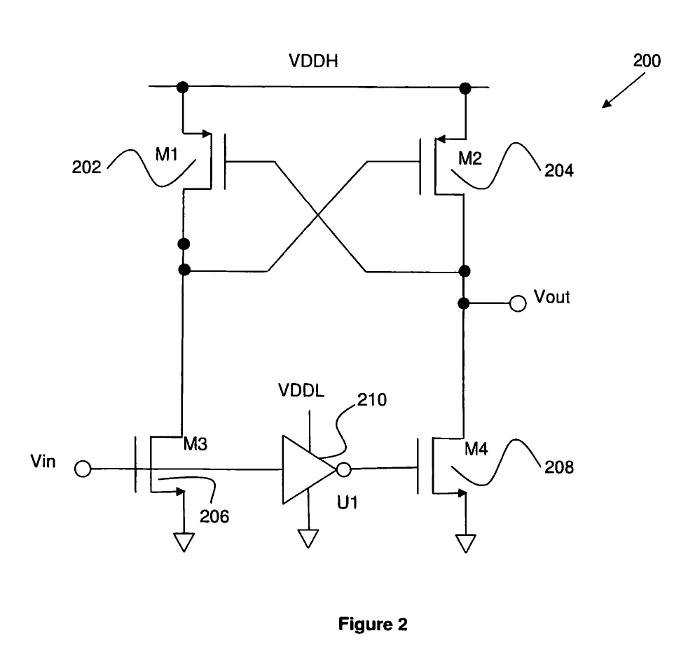

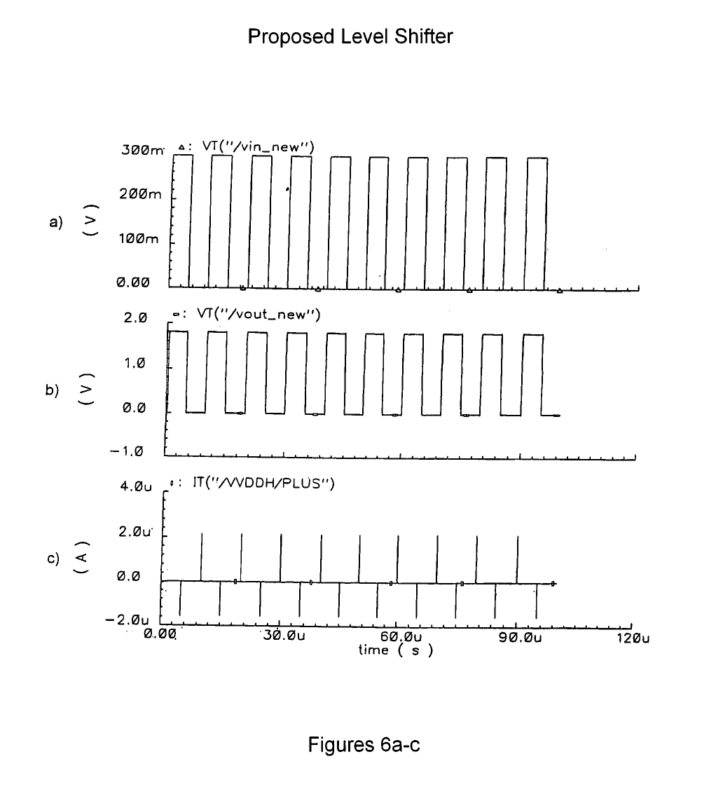

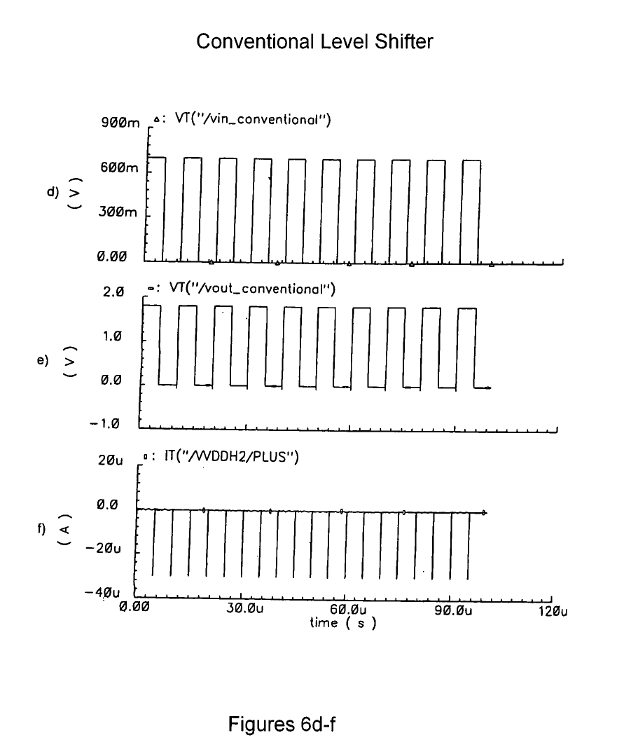

FIGS. 6a-c show graphical plots of input voltage, output voltage and current consumption for the circuit arrangement 500 and FIGS. 6d-f show graphical plots of input voltage, output voltage and current consumption for the conventional level shifter 200 of FIG. 2. For a 100 KHz input voltage, the conventional level shifter 200 consumes about 3.15 μW while the circuit arrangement 500 consumes about 31.15 nW. The circuit arrangement 500 is more energy efficient than the conventional level shifter 200. Furthermore, the conventional level shifter 200 requires the VDDL voltage to be greater than about 0.7V (which may be greater than a threshold voltage of a transistor) for proper operations. The conventional level shifter 200 is not sub-threshold input compatible. In contrast, the circuit arrangement 500 can work with a VDDL voltage of about 0.3V (which may be lower than a threshold voltage of a transistor). Thus, the circuit arrangement 500 can work at sub-threshold level.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

In this document, the following documents are cited:
[1] V. M. Elzakker, A. J. M. Tuijl, P. F. J. Geraedts, D. Schinkel, E. A. M. Klumperink, B. Nauta., “A 1.9 uW 4.4 fJ/conversion-step, 10 bit, 1 MS/s charge redistribution ADC,”. IEEE International Solid-State Circuits Conference (ISSCC), 2008
[2] J. M. Rabaey, A. Chandrakasan, B. Nikolic, Digital Integrated Circuits: A Design Perspective. 2^{nd} Edition, Prentice-Hall, 2003, pp. 604-605
[3] I. J. Chang, J. J. Kim, K. Roy, “Robust Level Converter Design for Sub-threshold Logic,” Low Power Electronics and Design, ISIPED '06, pp. 14-19, 2006
[4] T. Cho, P. R. Gray, “A 10 b 20 MSamples/s, 35 mW pipeline A/D Converter,” IEEE Journal of Solid-State Circuits, Vol. 27, no. 3, pp. 166-172, March 1995
[5] R. Lotfi, R. Majidi, M. Maymandi-Nejad, W. A. Serdijn, “An Ultra-Low-Power 10 Bit 100 KS/s successive Approximation analog-to-Digital converter,” Int. Symp. Circuits Syst. (ISCAS), pp. 1117-1120, 2009
[6] M. J. Lencioni, “Level Shifter Circuit,” U.S. Pat. No. 6,819,159 B1, Nov. 16, 2004
[7] S. Fujimoto, Y. Himeno, “Level Shifter Control Circuit with Delayed Switchover to Low-Power Level-Shifter,” U.S. Pat. No. 6,920,570 B2, Jul. 19, 2005

What is claimed is:

1. Circuit arrangement, comprising:
a first transistor, a second transistor, a third transistor, and a fourth transistor respectively comprising a first terminal, a second terminal, and a control terminal,
a first capacitor and a second capacitor respectively comprising a first terminal and a second terminal,
an inverter comprising an input terminal and an output terminal, and
a circuit arrangement input terminal and a first circuit arrangement output terminal,
wherein the first terminals of the first transistor, the second transistor and the third transistor are connected with each other,
wherein the second terminal of the first transistor is connected to the control terminal of the second transistor and to the first terminal of the first capacitor, and wherein the second terminal of the second transistor is connected to the control terminal of the first transistor, to the control terminal of the third transistor, and to the first terminal of the second capacitor,
wherein the second terminal of the first capacitor is connected to the input terminal of the inverter, and wherein the second terminal of the second capacitor is connected to the output terminal of the inverter,
wherein the output terminal of the inverter is connected to the control terminal of the fourth transistor,
wherein the second terminal of the third transistor is coupled to the first terminal of the fourth transistor,
wherein the circuit arrangement input terminal is connected to the input terminal of the inverter,
wherein the first circuit arrangement output terminal is connected between the second terminal of the third transistor and the first terminal of the fourth transistor.

2. The circuit arrangement according to claim 1,
further comprising a fifth transistor and a sixth transistor respectively comprising a first terminal, a second terminal and a control terminal,
further comprising a second circuit arrangement output terminal,
wherein the first terminal of the fifth transistor is coupled to the first terminals of the first, second and third transistor,
wherein the control terminal of the fifth transistor is coupled to the second terminal of the first transistor,
wherein the first terminal of the sixth transistor is coupled to the second terminal of the fifth transistor,
wherein the control terminal of the sixth transistor is coupled to the circuit arrangement input terminal, and
wherein the second circuit arrangement output terminal is connected between the second terminal of the fifth transistor and the first terminal of the sixth terminal.

3. The circuit arrangement according to claim 2,
wherein the inverter comprises a first voltage input terminal and a second voltage input terminal, and wherein the inverter is adapted to set the output terminal of the inverter to one of the voltages supplied to the first voltage input terminal and the second voltage input terminal, respectively, in dependence on the voltage supplied to the input terminal of the inverter.

4. The circuit arrangement according to claim 2,
wherein the first terminals of the first transistor, the second transistor, the third transistor, and the fifth transistor are set to a high power supply voltage VDDH, the first voltage supply terminal set to a low power supply voltage VDDL, whereas the second voltage supply terminal as well as the second terminals of the fourth and sixth transistor are respectively set to a fixed voltage which is lower than the low power supply voltage VDDL.

5. The circuit arrangement according to claim 4,
wherein the circuit arrangement is adapted such that it operates at a plurality of ratios [VDDH voltage/VDDL voltage].

6. The circuit arrangement according to claim 4,
wherein the circuit arrangement is adapted such that, during the operation of the circuit arrangement, each of the first capacitor and the second capacitor is charged to VDDH-VDDL.

7. The circuit arrangement according to claim 4,
wherein the circuit arrangement is adapted such that, during the operation of the circuit arrangement, the voltages of all internal nodes only change by VDDL, respectively.

8. The circuit arrangement according to claim 4,
wherein the VDDL voltage is a sub-threshold voltage with regard to the threshold voltage of the third, fourth, fifth and sixth transistor.

10. The circuit arrangement according to claim 8,
wherein the VDDL voltage is up to 30% higher or up to 30% lower than the threshold voltage of the third, fourth, fifth and sixth transistor.

11. The circuit arrangement according to claim 4,
wherein the third, fourth, fifth and sixth transistor are respectively 1.8V transistors having a threshold voltage of 0.4V, wherein the VDDL voltage is set to 0.3V.

12. The circuit arrangement according to claim 4,
wherein the circuit arrangement is adapted such that, during the operation of the circuit arrangement, the voltage Vout generated at the first circuit arrangement output terminal and the second circuit arrangement output terminal respectively ranges between the fixed voltage and VDDH.

13. The circuit arrangement according to claim 12,
wherein the VDDH voltage is below the maximum drain source voltage Vds.

14. The circuit arrangement according to claim 13,
wherein the third, fourth, fifth and sixth transistor are respectively 1.8V transistors, and
wherein the VDDH voltage is 1.8V.

15. The circuit arrangement according to claim 1,
wherein the circuit arrangement is a level shifter.

16. The circuit arrangement according to claim 15,
wherein the level shifter is part of a circuitry in which slower transistor switching speeds of the third, fourth, fifth and sixth transistor due to sub-threshold voltage transistor operations can be tolerated.

17. The circuit arrangement according to claim 16,
wherein the level shifter is part of a SAR analogue-to-digital converter.

18. The circuit arrangement according to claim 1,
wherein the first transistor, the second transistor, the third transistor, fourth transistor, fifth transistor, and sixth transistor respectively are field effect transistors, wherein the first terminals and second terminals of the first to sixth transistors respectively are source/drain terminals, and wherein the control terminals of the first to sixth transistors respectively are gate terminals.
